(19) United States
(12) Patent Application Publication
(10) Pub. No.: US 2025/0128519 A1
(43) Pub. Date: Apr. 24, 2025

(54) INKJET PRINTING DEVICE

(71) Applicant: Samsung Display Co., LTD., Yongin-si (KR)

(72) Inventors: Lae Ho KIM, Yongin-si (KR); Yu KONTA, Yongin-si (KR); Myung Soo HUH, Yongin-si (KR); Jae Bum PAHK, Yongin-si (KR); Jai Hyuk CHOI, Yongin-si (KR)

(21) Appl. No.: 18/731,080

(22) Filed: May 31, 2024

(30) Foreign Application Priority Data
Oct. 23, 2023 (KR) 10-2023-0142475

(51) Int. Cl. B41J 2/185; B41J 2/175; B41J 2/21; B41J 3/407

(52) U.S. Cl. CPC B41J 2/185; B41J 2/211; B41J 3/407; B41J 2002/17573

(57) ABSTRACT

An inkjet printing device includes: an inkjet head; an ink supply device connected to the inkjet head; a purge bath below the inkjet head, and connected to the ink supply device; a first channel connecting the purge bath and the ink supply device; and a densitometer in the first channel.

### CROSS-REFERENCE TO RELATED APPLICATION

The present application claims priority to and the benefit of Korean Patent Application No. 10-2023-0142475, filed on Oct. 23, 2023, in the Korean Intellectual Property Office, the entire disclosure of which is incorporated herein by reference.

### BACKGROUND

### 1. Field

Aspects of some embodiments of the present disclosure relate to an inkjet printing device.

### 2. Description of the Related Art

The importance of display devices has steadily increased with the development of multimedia technology. Such display devices include, for example, a liquid crystal display (LCD), an organic light emitting display (OLED), and the like. Such display devices may be utilized with, or incorporated into, various mobile electronic devices, for example, portable electronic devices such as smart phones, smart watches, and tablet PCs.

The organic light emitting display includes a display panel including an organic light emitting element. In the organic light emitting element, a cathode electrode, and an anode electrode are arranged with respect to an organic light emitting layer, and visible light is generated from the organic light emitting layer connected to both electrodes when a voltage is applied to both two electrodes.

Meanwhile, an inkjet printing device may be used to form the organic light emitting layer of the organic light emitting display. In the inkjet printing device, an ink or solution (e.g., a predetermined ink or solution) may be supplied to an inkjet head, and the inkjet head may perform a process of ejecting the ink or solution on a substrate to be processed (e.g., a target substrate) while the substrate to be processed reciprocates.

The above information disclosed in this Background section is only for enhancement of understanding of the background and therefore the information discussed in this Background section does not necessarily constitute prior art.

### SUMMARY

Aspects of some embodiments of the present disclosure include an inkjet printing device with a relatively increased ink reuse rate.

Aspects of some embodiments of the present disclosure may also include an inkjet printing device with relatively improved reliability of ink quality.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to some embodiments of the present disclosure, an inkjet printing device includes, an inkjet head, an ink supply device connected to the inkjet head, a purge bath below the inkjet head, and connected to the ink supply device, a first channel connecting the purge bath and the ink supply device, and a densitometer in the first channel.

According to some embodiments, the densitometer comprises, a measurement source generator, a measurement source detector configured to detect a measurement source generated from the measurement source generator, and a controller configured to receive information on the measurement source from the measurement source detector and the measurement source generator, respectively.

According to some embodiments, the measurement source generator and the measurement source detector are located on opposite sides with the first channel interposed therebetween.

According to some embodiments, the measurement source generator and the measurement source detector are located on the same side with respect to the first channel.

According to some embodiments, the measurement source generated from the measurement source generator interacts with ink located in the first channel.

According to some embodiments, the measurement source generator provides, to the controller, a first signal containing information on the measurement source generated from the measurement source generator, the measurement source detector provides, to the controller, a second signal containing information on the measurement source that has interacted with the ink, and the controller generates a third signal based on the first signal and the second signal.

According to some embodiments, the inkjet printing device may further comprise a solvent supply device connected to at least one of the purge bath, the first channel, or the ink supply device, wherein the controller is configured to provide the third signal to the solvent supply device.

According to some embodiments, the solvent supply device that has received the third signal is configured to supply a solvent of the ink to at least one of the purge bath, the first channel, or the ink supply device.

According to some embodiments, the inkjet printing device may further comprise a filter between the densitometer and the purge bath.

According to some embodiments, the purge bath comprises a door that controls opening and closing of the purge bath.

According to some embodiments, the door comprises a door driver configured to provide a driving force to the door.

According to some embodiments, the inkjet printing device may further comprise, a suction channel connecting the inkjet head and the door of the purge bath, and a suction device connected to the suction channel.

According to some embodiments, the door comprises a suction opening communicating with the suction channel, and the suction opening is configured to move along the suction channel.

According to some embodiments, an inner wall of the purge bath comprises a superhydrophobic coating film.

According to some embodiments, a level of the ink in the purge bath is maintained at a constant level.

According to some embodiments, the inkjet printing device may further comprise a removal tank connected to the purge bath, wherein the removal tank is not connected to the ink supply device.

According to some embodiments, the inkjet printing device may further comprise a second channel connecting the purge bath and the ink supply device, and different from the first channel, wherein ink flow directions of the first channel and the second channel are different.

According to some embodiments, the inkjet printing device may further comprise a blade located between the inkjet head and the purge bath, wherein the blade is configured to wipe a bottom surface of the inkjet head.

According to some embodiments of the present disclosure, an inkjet printing device includes, an ink supply device, an ink storage device configured to receive ink from the ink supply device, an inkjet head configured to receive ink from the ink storage device, a purge bath configured to collect ink ejected from the inkjet head, a first channel configured to move the ink from the purge bath to the ink supply device, a densitometer configured to measure a concentration of the ink located in the first channel, and a solvent supply device configured to supply a solvent of the ink to at least one of the ink supply device, the purge bath, or the first channel.

According to some embodiments, the inkjet printing device may further comprise a first pump in the first channel, and configured to provide a driving force from the purge bath toward the ink supply device.

According to some embodiments, the inkjet printing device may further comprise a second channel different from the first channel, and configured to move the ink from the ink supply device to the purge bath.

According to some embodiments, the inkjet printing device may further comprise a third channel configured to move the solvent of the ink from the solvent supply device to at least one of the ink supply device, the purge bath, or the first channel.

According to some embodiments, the inkjet printing device may further comprise a second pump in the third channel, and configured to provide a driving force from the solvent supply device toward at least one of the ink supply device, the purge bath, or the first channel.

In an inkjet printing device according to some embodiments of the present disclosure, the ink reuse rate may be relatively increased.

In an inkjet printing device according to some embodiments of the present disclosure, the reliability of ink quality may be relatively improved.

However, the characteristics of embodiments of the present disclosure are not limited to those described above and various other characteristics are incorporated herein.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a plan view illustrating a display device according to some embodiments;

FIG. 2 is a cross-sectional view taken along the line X1-X1′ of FIG. 1 according to some embodiments;

FIG. 3 is an enlarged view of the area A of FIG. 2 according to some embodiments;

FIG. 4 is a diagram showing an equivalent circuit of a circuit layer according to some embodiments;

FIG. 5 is a cross-sectional view showing a state in which an inkjet printing device is performing a printing process according to some embodiments;

FIG. 6 is a cross-sectional view showing a state in which an inkjet printing device is performing a head care process according to some embodiments;

FIG. 7 is a cross-sectional view showing a state in which an inkjet printing device has completed the head care process according to some embodiments;

FIG. 8 is an enlarged view of the area B of FIG. 6 according to some embodiments;

FIG. 9 is a schematic block diagram showing a densitometer according to some embodiments;

FIG. 10 is a schematic block diagram showing a densitometer according to some embodiments;

FIG. 11 is a cross-sectional view of an inkjet printing device according to some embodiments;

FIG. 12 is a bottom view showing an inkjet head of an inkjet printing device according to some embodiments;

FIGS. 13 and 14 are cross-sectional views of an inkjet printing device according to some embodiments; and

FIGS. 15 and 16 are cross-sectional views of an inkjet printing device according to some embodiments.

### DETAILED DESCRIPTION

Aspects of some embodiments of the present disclosure will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be more thorough and more complete, and will more fully convey the scope of embodiments according to the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, aspects of some embodiments of the present disclosure will be described in more detail with reference to the accompanying drawings.

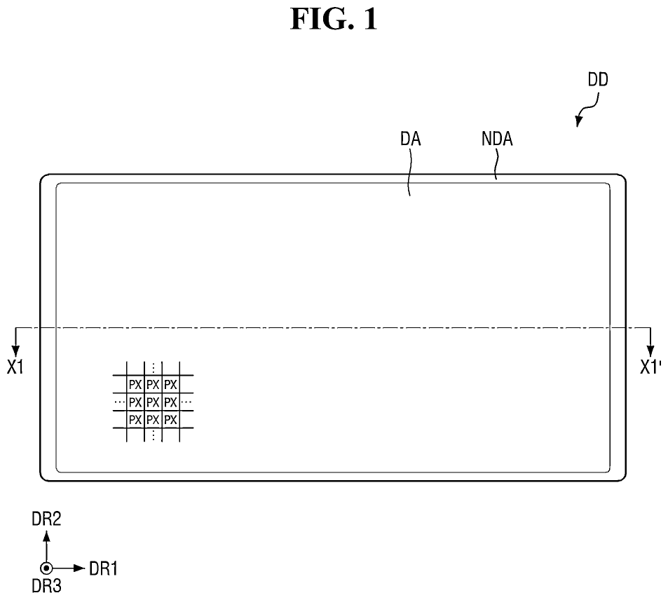

FIG. 1 is a plan view illustrating a display device according to some embodiments.

Referring to FIG. 1, a display device DD may refer to any electronic device providing a display screen. The display device DD may display moving images (e.g., video images) or a still image (e.g., static images). Examples of the display device DD may include a television, a laptop computer, a monitor, a billboard, an Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which provide a display screen.

According to some embodiments, the display device DD may have a rectangular shape (e.g., or a generally rectangular shape) in a plan view. The display device DD may include two long sides extending in a first direction DR1 and two short sides extending in a second direction DR2 intersecting the first direction DR1. A corner where the long side and the short side of the display device DD meet may have a right angle. However, embodiments according to the present disclosure are not limited thereto, and the corner may have a curved surface. According to some embodiments, the long side may extend in the second direction DR2, and the short side may extend in the first direction DR1. The planar shape of the display device DD is not limited to the illustrated shape, but may have a circular shape or other shapes.

In the illustrated figure, the first direction DR1 and the second direction DR2 cross each other as horizontal directions. For example, the first direction DR1 and the second direction DR2 may be orthogonal to each other. In addition, the third direction DR3 crosses the first direction DR1 and the second direction DR2, and may be, for example, perpendicular directions orthogonal to each other. Unless otherwise defined, in the present specification, directions indicated by arrows of the first to third directions DR1, DR2, and DR3 may be referred to as one side, and the opposite directions thereto may be referred to as the other side.

The display device DD may include a display panel which provides a display screen. Examples of the display panel may include an inorganic light emitting diode display panel, an organic light emitting display panel, a quantum dot light emitting display panel, a plasma display panel and a field emission display panel. In the following description, a case where an organic light emitting diode display panel is applied as a display panel will be described, but embodiments according to the present disclosure are not limited thereto, and other display panels may be applied within the same scope of technical spirit.

The display device DD may include a display area DA and a non-display area NDA arranged around (e.g., in a periphery or outside a footprint of) the display area DA. The display area DA is an area where a screen is (or images are) displayed, and the non-display area NDA is an area where a screen is not (or images are not) displayed. The display area DA may also be referred to as an active region, and the non-display area NDA may also be referred to as a non-active region. The display area DA substantially occupies the center of the display device DD, and the non-display area NDA may be arranged to surround the display area DA.

The display area DA may include a plurality of pixels PX. The plurality of pixels PX may be arranged in a matrix. The shape of each pixel PX may be a rectangular or square shape in a plan view. However, embodiments according to the present disclosure are not limited thereto, and it may be a rhombic shape in which each side is inclined with respect to one direction.

As described above, the non-display area NDA may be arranged around the display area DA. The non-display area NDA may completely or partially surround the display area DA. The display area DA may have a rectangular shape, and the non-display area NDA may be arranged adjacent to four sides of the display area DA. The non-display area NDA may form a bezel of the display device DD. Wires or circuit drivers included in the display device DD may be located in the non-display area NDA, or external devices may be mounted thereon.

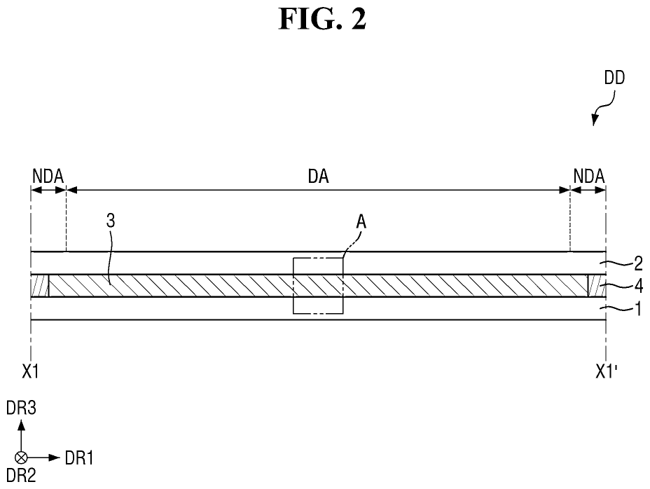

FIG. 2 is a cross-sectional view taken along line X1-X1′ of FIG. 1.

Referring to FIG. 2, the display device DD may include a display substrate 1, a color conversion substrate 2 facing the display substrate 1, a sealing portion 4 that bonds the display substrate 1 to the color conversion substrate 2, and a filler 3 filled between the display substrate 1 and the color conversion substrate 2.

The display substrate 1 may include elements and circuits for displaying an image, for example, a pixel circuit such as a switching element, a self-light emitting element, and a pixel defining layer defining an emission area and a non-emission area. According to some embodiments, the self-light emitting element may include at least one of an organic light emitting diode, a quantum dot light emitting diode, an inorganic micro light emitting diode (e.g., micro LED), or an inorganic nano light emitting diode (e.g., nano LED).

The color conversion substrate 2 may be positioned on the display substrate 1 to face the display substrate 1. According to some embodiments, the color conversion substrate 2 may include a color conversion pattern for converting the color of incident light. According to some embodiments, the color conversion pattern may include at least one of a color filter or a wavelength conversion pattern.

The sealing portion 4 may be located between the display substrate 1 and the color conversion substrate 2 in the non-display area NDA. The sealing portion 4 may be arranged along edges of the display substrate 1 and the color conversion substrate 2 in the non-display area NDA to surround (e.g., in a periphery or outside a footprint of) the display area DA in a plan view. The display substrate 1 and the color conversion substrate 2 may be bonded to each other through the sealing portion 4.

The filler 3 may be located in a space between the display substrate 1 and the color conversion substrate 2 surrounded by the sealing portion 4. The filler 3 may fill the space between the display substrate 1 and the color conversion substrate 2. The filler 3 may be made of a material that can transmit light. In some embodiments, the filler 3 may be omitted.

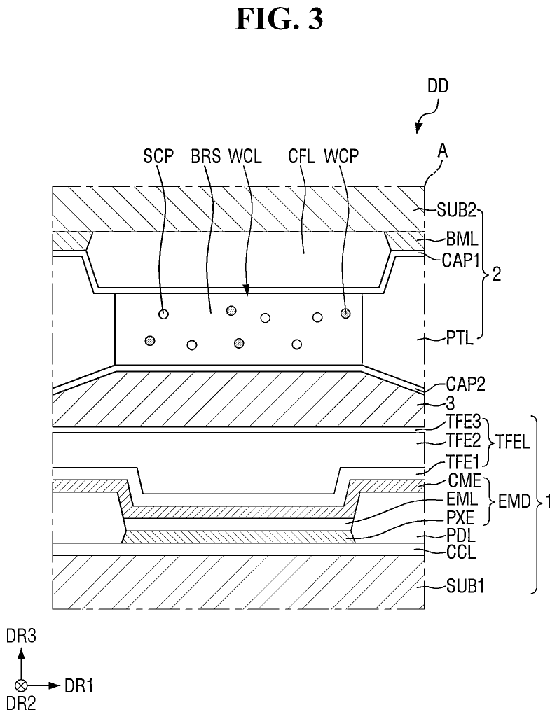

FIG. 3 is an enlarged view of the area A of FIG. 2.

Referring to FIG. 3, the display device DD may include the display substrate 1, the color conversion substrate 2 facing the display substrate 1, and the filler 3 filled between the display substrate 1 and the color conversion substrate 2.

The display substrate 1 may include a first base substrate SUB1, a circuit layer CCL, a pixel defining layer PDL, a light emitting element EMD, and a thin film encapsulation layer TFEL.

The first base substrate SUB1 may include a transparent material. For example, the first base substrate SUB1 may include a transparent insulating material such as glass, quartz, or the like. The first base substrate SUB1 may be a rigid substrate. However, the first base substrate SUB1 is not limited thereto. The first base substrate SUB1 may include plastic such as polyimide or the like, and may have a flexible property such that it can be twisted, bent, folded, or rolled.

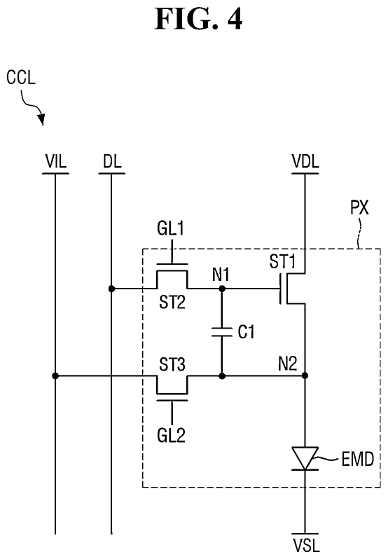

The circuit layer CCL may be located on the first base substrate SUB1. The circuit layer CCL may include a transistor for driving the light emitting element EMD and various circuit wires. The circuit layer CCL may be located between the first base substrate SUB1 and the light emitting element EMD. The circuit layer CCL will be described later with reference to FIG. 4.

The pixel defining layer PDL may be located on a pixel electrode PXE along the boundary of the pixel PX. The pixel defining layer PDL may include an opening that exposes at least a part of the pixel electrode PXE. The emission area and the non-emission area may be distinguished by the pixel defining layer PDL and the opening thereof.

The pixel defining layer PDL may include an organic insulating material such as acrylic resin, epoxy resin, phenolic resin, polyamide resin, polyimide resin, unsaturated polyester resin, polyphenylene resin, polyphenylenesulfide resin or benzocyclobutene (BCB). The pixel defining layer PDL may include an inorganic material.

The light emitting element EMD may be located on the circuit layer CCL. Although one pixel PX is illustrated in FIG. 3 to show one light emitting element EMD, the display substrate 1 may include a plurality of light emitting elements EMD arranged for each pixel PX.

The light emitting element EMD may include the pixel electrode PXE, a light emitting layer EML, and a common electrode CME.

The pixel electrode PXE may be located on the circuit layer CCL of the display substrate 1. The pixel electrode PXE may be a first electrode (e.g., an anode electrode) of the light emitting element EMD. The pixel electrode PXE may have a stacked structure formed by stacking a material layer having a high work function, such as indium tin oxide (ITO), indium zinc oxide (IZO), zinc oxide (ZnO) and indium oxide (In₂O₃), and a reflective material layer such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca), or a mixture thereof. The material layer having a high work function may be located above the reflective material layer and located closer to the light emitting layer EML. The pixel electrode PXE may have a multilayer structure such as ITO/Mg, ITO/MgF, ITO/Ag and ITO/Ag/ITO, but is not limited thereto.

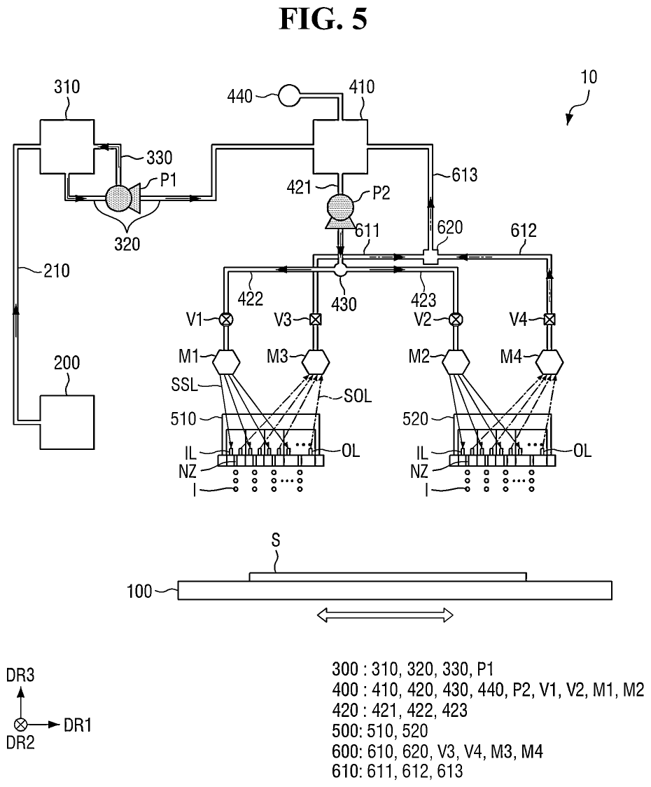

The light emitting layer EML may be located on the pixel electrode PXE exposed by the pixel defining layer PDL. According to some embodiments in which the display device DD is an organic light emitting display, the light emitting layers EML may include an organic layer having an organic material. The organic layer may have an organic light emitting layer, and in some cases, may further have at least one of a hole injection layer, a hole transport layer, an electron transport layer, or an electron injection layer as an auxiliary layer for light emission. According to some embodiments, when the display device DD is a micro LED display device, a nano LED display device, or the like, the light emitting layer EML may include an inorganic material such as an inorganic semiconductor. According to some embodiments, the light emitting layer EML may be formed using an inkjet printing device 10 (see FIG. 5) to be described in more detail later.

According to some embodiments, the wavelengths of light emitted from the respective light emitting layers EML may be the same regardless of the pixels PX. For example, the light emitting layer EML of each pixel PX may emit blue light or ultraviolet rays, and the color conversion substrate 2 which will be described later may include a wavelength conversion layer WCL, thereby displaying a color for each pixel PX. According to some embodiments, the wavelength of light emitted by each light emitting layer EML may be different for each pixel PX.

The common electrode CME may be arranged on the light emitting layer EML. The common electrode CME may be continuous across the pixels PX. The common electrode CME may be a full surface electrode arranged over the entire surface across all the pixels PX. The common electrode CME may be a second electrode (e.g., a cathode electrode) of the light emitting element EMD. The common electrode CME may include a material layer having a low work function, such as Li, Ca, LiF/Ca, LiF/Al, Al, Mg, Ag, Pt, Pd, Ni, Au Nd, Ir, Cr, BaF, Ba or a compound or mixture thereof (e.g., a mixture of Ag and Mg). The common electrode CME may further include a transparent metal oxide layer located on the material layer having a low work function.

The thin film encapsulation layer TFEL may be located on the common electrode CME. The thin film encapsulation layer TFEL may include a first inorganic layer TFE1, an organic layer TFE2, and a second inorganic layer TFE3.

The first inorganic layer TFE1 may be located on the light emitting element EMD. The first inorganic layer TFE1 may include silicon nitride (SiNx), silicon oxide (SiOx), silicon oxynitride (SiOxNy), or the like.

The organic layer TFE2 may be located on the first inorganic layer TFE1. The organic layer TFE2 may include an organic insulating material selected from the group consisting of acrylic resin, epoxy resin, phenolic resin, polyamide resin, polyimide resin, unsaturated polyester resin, polyphenylene ether resin, polyphenylenesulfide resin and benzocyclobutene (BCB).

The second inorganic layer TFE3 may be located on the organic layer TFE2. The second inorganic layer TFE3 may include the same material as the first inorganic layer TFE1 described above. For example, the second inorganic layer TFE3 may include silicon nitride (SiNx), silicon oxide (SiOx), silicon oxynitride (SiOxNy), or the like.

The color conversion substrate 2 may be arranged to face the display substrate 1 above the thin film encapsulation layer TFEL. For example, the color conversion substrate 2 may be located to face the display substrate 1 with the filler 3 interposed therebetween.

The color conversion substrate 2 may include a second base substrate SUB2, a light blocking member BML, a color filter layer CFL, a first capping layer CAP1, a partition wall PTL, the wavelength conversion layer WCL, and a second capping layer CAP2.

The second base substrate SUB2 may include a transparent material. For example, the second base substrate SUB2 may include a transparent insulating material such as glass, quartz, or the like. The second base substrate SUB2 may be a rigid substrate. However, the second base substrate SUB2 is not limited thereto. The second base substrate SUB2 may include plastic such as polyimide or the like, and may have a flexible property such that it can be twisted, bent, folded, or rolled.

The second base substrate SUB2 may be the same substrate as the first base substrate SUB1, but may have a different material, thickness, transmittance and the like. For example, the second base substrate SUB2 may have a higher transmittance than the first base substrate SUB1. The second base substrate SUB2 may be thicker or thinner than the first base substrate SUB1.

The light blocking member BML may be arranged along the boundary of the pixel PX on one surface of the second base substrate SUB2 facing the first base substrate SUB1. The light blocking member BML may overlap the pixel defining layer PDL of the display substrate 1. The light blocking member BML may include an opening that exposes one surface of the second base substrate SUB2, and may be formed in a lattice shape in a plan view.

The light blocking member BML may include an organic material. The light blocking member BML may reduce color distortion due to external light reflection by absorbing the external light. Further, the light blocking member BML may serve to prevent or reduce instances of light which is emitted from the light emitting layer EML entering the adjacent pixels PX.

The color filter layer CFL may be located on one surface of the second base substrate SUB2 on which the light blocking member BML is located. The color filter layer CFL may be located on one surface of the second base substrate SUB2 that is exposed through the opening of the light blocking member BML. In some embodiments, the color filter layer CFL may be formed using the inkjet printing device 10 (see FIG. 5) to be described in more detail later.

The color filter layer CFL may include a colorant such as a dye or pigment that absorbs wavelengths other than the corresponding color wavelength. The color filter layer CFL may include colorants of different colors for each pixel PX. For example, the color filter layer CFL may include a red colorant, a green colorant, and a blue colorant.

The first capping layer CAP1 may be located on the color filter layer CFL. The first capping layer CAP1 may prevent or reduce permeation of impurities such as moisture, air, or the like. Further, the first capping layer CAP1 may prevent or reduce instances of the colorants of the color filter layers CFL being diffused into other components.

The partition wall PTL may be located on the first capping layer CAP1. The partition wall PTL may be arranged to overlap the light blocking member BML. The partition wall PTL may include an opening exposing a region in which the color filter layer CFL is located. The partition wall PTL may include a photosensitive organic material, but embodiments according to the present disclosure are not limited thereto. The partition wall PTL may further include a light blocking material.

The wavelength conversion layer WCL may be located in the space exposed by the opening of the partition wall PTL. According to some embodiments, the wavelength conversion layer WCL may be formed using the inkjet printing device 10 (see FIG. 5) to be described in more detail later.

The wavelength conversion layer WCL may convert the wavelength of light incident from the light emitting layer EML. The wavelength conversion layer WCL may include a base resin BRS, and a scatterer SCP and a wavelength conversion material WCP located in the base resin BRS.

The base resin BRS may contain a light-transmissive organic material. For example, the base resin BRS may contain epoxy resin, acrylic resin, cardo resin, or imide resin.

The wavelength conversion material WCP may be a material that converts a color. The wavelength conversion material WCP may be a quantum dot, a quantum rod, a phosphor, or the like. Examples of the quantum dot may include group IV nanocrystal, group II-VI compound nanocrystal, group III-V compound nanocrystal, group IV-VI nanocrystal, and a combination thereof.

According to some embodiments, the wavelength conversion layer WCL may not include the wavelength conversion material WCP. When the wavelength conversion layer WCL does not include the wavelength conversion material WCP, it may serve as a light transmitting layer that transmits light.

The scatterer SCP may be a metal oxide particle or an organic particle. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), and the like. Examples of a material of the organic particles may include acrylic resin and urethane resin, and the like.

The second capping layer CAP2 may be located on the wavelength conversion layer WCL and the partition wall PTL. The second capping layer CAP2 may be arranged on the entire surface of the color conversion substrate 2. The second capping layer CAP2 may prevent or reduce permeation of impurities or contaminants such as moisture, air, or the like. The second capping layer CAP2 may be made of an inorganic material. The second capping layer CAP2 may include a material selected from the above-mentioned materials of the first capping layer CAP1. The second capping layer CAP2 and the first capping layer CAP1 may be made of the same material, but are not limited thereto.

The filler 3 may be located between the display substrate 1 and the color conversion substrate 2. The filler 3 may fill a space between the display substrate 1 and the color conversion substrate 2, and may serve to bond them to each other. The filler 3 may be located between the thin film encapsulation layer TFEL of the display substrate 1 and the second capping layer CAP2 of the color conversion substrate 2. The filler 3 may be formed of an Si-based organic material, an epoxy-based organic material, or the like, but embodiments according to the present disclosure are not limited thereto.

FIG. 4 is a diagram showing an equivalent circuit of a circuit layer according to some embodiments.

Referring to FIG. 4, the circuit layer CCL may include various wires for driving the light emitting element EMD. According to some embodiments, the circuit layer CCL may include a pixel circuit included in each pixel PX, a first voltage line VDL, an initialization voltage line VIL, a first gate line GL1, and a second gate line GL2, a data line DL, and a second voltage line VSL.

The pixel PX may include the pixel circuit and the light emitting element EMD. The pixel circuit may be connected to the first voltage line VDL, the initialization voltage line VIL, the first gate line GL1, the second gate line GL2, the data line DL, and the second voltage line VSL.

The first voltage line VDL may supply a driving voltage or a high potential voltage to the pixel circuit. The initialization voltage line VIL may supply an initialization voltage to the pixel circuit. The initialization voltage line VIL may receive a sensing signal from the pixel circuit. The second voltage line VSL may supply a low potential voltage to the light emitting element EMD. The first gate line GL1 may supply a first gate signal to the pixel circuit. The second gate line GL2 may supply a second gate signal to the pixel circuit. The data line DL may supply a data voltage to the pixel circuit.

The pixel circuit may include a first transistor ST1, a second transistor ST2, a third transistor ST3, and a first capacitor C1.

The first transistor ST1 may include a gate electrode, a drain electrode, and a source electrode. The gate electrode of the first transistor ST1 may be connected to a first node N1, the drain electrode thereof may be connected to the first voltage line VDL, and the source electrode thereof may be connected to a second node N2. The first transistor ST1 may control a drain-source current (or driving current) based on a data voltage applied to the gate electrode. The first transistor ST1 may be a driving transistor for driving the light emitting element EMD.

The light emitting element EMD may emit light by receiving a driving current. The light emission amount or the luminance of the light emitting element EMD may be proportional to the magnitude of the driving current. The light emitting element EMD may be an organic light emitting diode (OLED) having an organic light emitting layer, a quantum dot light emitting diode (LED) including a quantum dot light emitting layer, a micro LED, or an inorganic LED having an inorganic semiconductor.

The first electrode of the light emitting element EMD may be connected to the second node N2, and the second electrode of the light emitting element EMD may be connected to the second voltage line VSL. The first electrode of the light emitting element EMD may be connected to the source electrode of the first transistor ST1, the drain electrode of the third transistor ST3, and the second capacitor electrode of the first capacitor C1, through the second node N2.

The second transistor ST2 may be turned on by the first gate signal of the first gate line GL1 to electrically connect the data line DL to the first node N1 which is the gate electrode of the first transistor ST1. The second transistor ST2 may be turned on based on the first gate signal to supply the data voltage to the first node N1. The gate electrode of the second transistor ST2 may be connected to the first gate line GL1, the drain electrode thereof may be connected to the data line DL, and the source electrode thereof may be connected to the first node N1. The source electrode of the second transistor ST2 may be connected to the gate electrode of the first transistor ST1 and a first capacitor electrode of the first capacitor C1 through the first node N1. The second transistor ST2 may be a switching transistor for controlling the current flowing through the first transistor ST1 and the light emitting element EMD.

The third transistor ST3 may be turned on by the second gate signal of the second gate line GL2 to electrically connect the initialization voltage line VIL to the second node N2 which is the source electrode of the first transistor ST1. The third transistor ST3 may be turned on according to the second gate signal to supply the initialization voltage to the second node N2. The third transistor ST3 may be turned on according to the second gate signal to supply the sensing signal to the initialization voltage line VIL. The gate electrode of the third transistor ST3 may be connected to the second gate line GL2, the drain electrode thereof may be connected to the second node N2, and the source electrode thereof may be connected to the initialization voltage line VIL. The drain electrode of the third transistor ST3 may be connected to the source electrode of the first transistor ST1, the second capacitor electrode of the first capacitor C1, and the first electrode of the light emitting element EMD, through the second node N2. The third transistor ST3 may be a switching transistor for controlling the current flowing through the first transistor ST1 and the light emitting element EMD.

The first capacitor C1 may include a first capacitor electrode and a second capacitor electrode. The first capacitor electrode may be connected to the gate electrode of the first transistor ST1 and the source electrode of the second transistor ST2 through the first node N1. The second capacitor electrode may be connected to the source electrode of the first transistor ST1 and the first electrode of the light emitting element EMD through the second node N2. The second capacitor electrode may be connected to the drain electrode of the third transistor ST3. The first capacitor C1 may store a capacitance using the voltage difference between the first capacitor electrode and the second capacitor electrode.

Among various patterns of the display device DD, for example, the layers such as the light emitting layer EML, the color filter layer CFL, and the wavelength conversion layer WCL may be formed using the inkjet printing device 10 (see FIG. 5) to be described in more detail later. Hereinafter, the inkjet printing device 10 (see FIG. 5) used to form such patterns will be described in more detail.

FIG. 5 is a cross-sectional view showing a state in which an inkjet printing device according to some embodiments is performing a printing process.

Referring to FIG. 5, the inkjet printing device 10 may perform a printing process. The printing process may refer to a process of forming a specific pattern on an object using an ink or the like. For example, as described above, when the inkjet printing device 10 is used to manufacture the display device DD (see FIG. 1), the printing process may refer to a process of forming various patterns included in the display device DD (see FIG. 1), for example, the layers such as the light emitting layer EML (see FIG. 3), the color filter layer CFL (see FIG. 3), and the wavelength conversion layer WCL (see FIG. 3).

The inkjet printing device 10 may include a stage 100, an ink supply device 200, a buffer circulation system 300, a supply circulation system 400, an inkjet head 500, and a discharge circulation system 600.

The stage 100 may provide a space where a target substrate S is mounted. Here, the target substrate S may be the display device DD (see FIG. 1) described above. The stage 100 may have a flat plate shape. The planar shape of the stage 100 may be similar to the planar shape of the target substrate. For example, the planar shape of the stage 100 may be a substantially rectangular shape in a plan view, but embodiments according to the present disclosure not limited thereto, and the stage 100 may have any suitable shape in a plan view.

According to some embodiments, the stage 100 may move in the first direction DR1 and/or the second direction DR2. According to some embodiments, the inkjet printing device 10 may further include a separate driver for providing a driving force to the stage 100. When the separate driver for providing a driving force to the stage 100 is further included, the inkjet head 500 may eject an ink I to the target substrate S while the stage 100 is moving instead of the inkjet head 500. However, embodiments according to the present disclosure are not limited thereto, and both the stage 100 and the inkjet head 500 may move.

The ink supply device 200 may store the ink I, and provide the stored ink I to the buffer circulation system 300. The ink I, which is a solution, may include a solute and a solvent that dissolves the solute. The solution and the solute may contain different materials depending on the configuration of the display device DD (see FIG. 1) to be printed.

The ink supply device 200 may further include an initial supply channel 210. The initial supply channel 210 may connect the ink supply device 200 and the buffer circulation system 300. The ink I of the ink supply device 200 may move to the buffer circulation system 300 through the initial supply channel 210.

According to some embodiments, a pump located in the initial supply channel 210 may be further included. The pump may provide a driving force so that some of the ink I stored in the ink supply device 200 may move to the buffer circulation system 300 through the initial supply channel 210. The pump may be a fluid pump that transmits a power to a fluid such as the ink I.

In some embodiments, the ink supply device 200 may supply the ink I to the inkjet head 500 through an ink storage device, instead of directly supplying the ink I to the inkjet head 500. The ink storage device may include a buffer storage device 310 of the buffer circulation system 300 and a supply storage device 410 of the supply circulation system 400.

The buffer circulation system 300 may be a buffer circulation system for preventing or reducing ink particles of the ink I from precipitating in the inkjet printing device 10 and removing bubbles generated in the ink I.

The buffer circulation system 300 may include the buffer storage device 310, a first buffer channel 320, a second buffer channel 330, and a first pump P1.

The buffer storage device 310 may temporarily store the ink I of the ink supply device 200 before the ink I moves to the supply circulation system 400.

The first buffer channel 320 may connect the buffer storage device 310 and the supply circulation system 400. At least some of the ink I of the buffer storage device 310 may move to the supply circulation system 400 through the first buffer channel 320.

The second buffer channel 330 may connect the first buffer channel 320 and the buffer storage device 310. At least some of the ink I of the first buffer channel 320 may return to the buffer storage device 310 through the second buffer channel 330. Accordingly, the negative pressure of the supply circulation system 400 and the flow amount of the ink I in the supply circulation system 400 may be maintained at a constant level. Further, even when the ink I is not ejected for a long time, the ink I may continuously circulate to prevent or reduce instances of ink particles precipitating in the buffer circulation system 300.

The first pump P1 may provide a driving force so that some of the ink I stored in the buffer storage device 310 may move to the supply circulation system 400 through the first buffer channel 320. Further, the first pump P1 may provide a driving force so that some of the ink I moving along the first buffer channel 320 may return to the buffer storage device 310. For example, the first pump P1 may be a fluid pump that transmits a power to a fluid such as the ink I.

In some embodiments, the first pump P1 may include a plurality of pumps. For example, the first pump P1 may include a first sub-pump that provides a driving force so that some of the ink I stored in the buffer storage device 310 may move to the supply circulation system 400 through the first buffer channel 320, and a second sub-pump that provides a driving force so that some of the ink I moving along the first buffer channel 320 may return to the buffer storage device 310.

The supply circulation system 400 may be a supply circulation system for supplying the ink I to the inkjet head 500 in the inkjet printing device 10 by providing a negative pressure.

The supply circulation system 400 may include the supply storage device 410, a supply channel 420, a branch point 430, a pressure regulator 440, a second pump P2, one or more supply valves V1 and V2, and one or more supply manifolds M1 and M2.

The supply storage device 410 may store the ink I of the buffer storage device 310 before the ink I moves to the inkjet head 500.

The supply channel 420 may include one or more supply channels 421, 422, and 423. For example, the supply channel 420 may include the first supply channel 421, the second supply channel 422, and the third supply channel 423. The branch point 430 may include at least one branch point. However, the number of the supply channels 420 and the number of the branch points 430 are not limited thereto, and may be variously changed depending on the number of the inkjet heads 500 and the design structure of the inkjet printing device 10.

The first supply channel 421 may connect the supply storage device 410 and the branch point 430. The branch point 430 may be a branch point where the first supply channel 421 branches into the second supply channel 422 and the third supply channel 423.

The second supply channel 422 may connect the branch point 430 and the first manifold M1. The third supply channel 423 may connect the branch point 430 and the second manifold M2. The second supply channel 422 and the third supply channel 423 may supply the ink I to a first inkjet head 510 and a second inkjet head 520, respectively.

The pressure regulator 440 may provide a negative pressure to the supply circulation system 400. For example, the pressure regulator 440 may be a vacuum regulator or an air regulator. The pressure regulator 440 may provide a negative pressure to the supply circulation system 400 so that the ink I located in a nozzle NZ of the inkjet head 500 may form a meniscus. Further, arbitrary ejection of the ink I located in the nozzle NZ of the inkjet head 500 due to gravity may be prevented or reduced.

The second pump P2 may provide a driving force so that the ink I stored in the supply storage device 410 moves to the inkjet head 500 through the supply channel 420. For example, the second pump P2 may be a fluid pump that transmits a power to a fluid such as the ink I.

The supply valves V1 and V2 may control whether or not the ink I flows in the supply channel 420. According to some embodiments, the supply valves V1 and V2 may be on/off valves. For example, when the supply valves V1 and V2 are open, the ink I may pass through the supply channel 420, and when the supply valves V1 and V2 are closed, the ink I may not pass through the supply channel 420.

According to some embodiments, the supply valves V1 and V2 may include the first valve V1 and the second valve V2. The first valve V1 may be located in the second supply channel 422 to control whether or not the ink I flows in the second supply channel 422. The second valve V2 may be located in the third supply channel 423 to control whether or not the ink I flows in the third supply channel 423. However, the number of the supply valves V1 and V2 is not limited thereto, and may be variously changed depending on the number of the inkjet heads 500 and the design structure of the inkjet printing device 10.

The supply manifolds M1 and M2 may supply the ink I to each inlet IL of the inkjet head 500. For example, the supply manifolds M1 and M2 may branch the supply channel 420 into one or more sub-supply channels SSL respectively connected to one or more inlets IL.

According to some embodiments, the supply manifolds M1 and M2 may include the first manifold M1 and the second manifold M2. The first manifold M1 may be connected to the second supply channel 422 to supply an ink to one or more inlets IL of the first inkjet head 510. The second manifold M2 may be connected to the third supply channel 423 to supply an ink to one or more inlets IL of the second inkjet head 520. However, the number of the supply manifolds M1 and M2 is not limited thereto, and may be variously changed depending on the number of the inkjet heads 500 and the design structure of the inkjet printing device 10.

The inkjet head 500 may be located on the stage 100. The inkjet head 500 may eject the ink I toward the stage 100. The ink I ejected from the inkjet head 500 may be mounted on the target substrate S placed on the stage 100.

In some embodiments, the inkjet head 500 may move in the first direction DR1 and/or the second direction DR2. According to some embodiments, the inkjet printing device 10 may further include a separate driver for providing a driving force to the inkjet head 500. If the separate driver for providing a driving force to the inkjet head 500 is further included, the inkjet head 500 may move instead of the stage 100 to eject the ink I onto the target substrate S. However, embodiments according to the present disclosure are not limited thereto, and both the stage 100 and the inkjet head 500 may move.

The inkjet head 500 may include at least one inlet IL, at least one outlet OL, and at least one nozzle NZ.

The inlet IL may be an entrance through which the ink I enters the inkjet head 500. One or more inlets IL may be connected to each of the supply manifolds M1 and M2. The ink I supplied from the supply manifolds M1 and M2 may be ejected onto the stage 100 through the nozzle NZ, or may move to the discharge circulation system 600 through the outlet OL.

The nozzle NZ may face the stage 100. The ink I supplied from the inlet IL may be ejected onto the stage 100 through at least one nozzle NZ.

The outlet OL may be an outlet through which the ink I is discharged from the inkjet head 500. One or more outlets OL may be connected to each of discharge manifolds M3 and M4. The ink I remaining in the inkjet head 500 without being ejected through the nozzle NZ may move to the discharge manifolds M3 and M4 through the outlet OL.

According to some embodiments, the inkjet head 500 may include the first inkjet head 510 and the second inkjet head 520. The first inkjet head 510 and the second inkjet head 520 may be arranged along the first direction DR1 or the second direction DR2. As shown in the drawing, the first inkjet head 510 and the second inkjet head 520 may be arranged to be spaced apart from each other, but embodiments according to the present disclosure are not limited thereto. Although a case where the number of the inkjet heads 500 is two is described as an example, embodiments according to the present disclosure are not limited thereto, and the number of the inkjet heads 500 may vary.

The discharge circulation system 600 may be a discharge circulation system for reusing the ink I remaining in the inkjet head 500 without being ejected through the nozzle NZ.

The discharge circulation system 600 may include a discharge channel 610, a joining point 620, one or more discharge valves V3 and V4, and one or more discharge manifolds M3 and M4.

The discharge manifolds M3 and M4 may discharge the ink I from each outlet OL of the inkjet head 500. For example, the discharge manifolds M3 and M4 may combine one or more sub-discharge channels SOL connected to one or more outlets OL into the discharge channel 610.

According to some embodiments, the discharge manifolds M3 and M4 may include the third manifold M3 and the fourth manifold M4. The third manifold M3 may be connected to a first discharge channel 611 to discharge the ink I from the outlet OL of the first inkjet head 510. The fourth manifold M4 may be connected to a second discharge channel 612 to discharge the ink I from the outlet OL of the second inkjet head 520. However, the number of the discharge manifolds M3 and M4 is not limited thereto, and may be variously changed depending on the number of the inkjet heads 500 and the design structure of the inkjet printing device 10.

The discharge channel 610 may include one or more discharge channel 611, 612, and 613. For example, the discharge channel 610 may include the first discharge channel 611, the second discharge channel 612, and a third discharge channel 613. The joining point 620 may include at least one joining point. However, the number of the discharge channels 610 and the number of the joining points 620 are not limited thereto, and may be variously changed depending on the number of the inkjet heads 500 and the design structure of the inkjet printing device 10.

The first discharge channel 611 may connect the joining point 620 and the third manifold M3. The second discharge channel 612 may connect the joining point 620 and the fourth manifold M4. The joining point 620 may be a joining point where the first discharge channel 611 and the second discharge channel 612 are combined into the third discharge channel 613.

The third discharge channel 613 may connect the joining point 620 and the supply storage device 410. Because the third discharge channel 613 resupplies the ink I to the supply storage device 410, the ink I that has not been ejected may be reused.

The discharge valves V3 and V4 may control whether or not the ink I flows in the discharge channel 610. According to some embodiments, the discharge valves V3 and V4 may be on/off valves. For example, when the discharge valves V3 and V4 are open, the ink I may pass through the discharge channel 610, and when the discharge valves V3 and V4 are closed, the ink I may not pass through the discharge channel 610.

According to some embodiments, one or more discharge valves V3 and V4 may include the third valve V3 and the fourth valve V4. The third valve V3 may be located in the first discharge channel 611 to control whether or not the ink I flows in the first discharge channel 611. The fourth valve V4 may be located in the second discharge channel 612 to control whether or not the ink I flows in the second discharge channel 612. However, the number of the discharge valves V3 and V4 is not limited thereto, and may be variously changed depending on the number of the inkjet heads 500 and the design structure of the inkjet printing device 10.

In the discharge circulation system 600, the ink I may move by the driving force of the supply circulation system 400. For example, the ink I may circulate through the supply circulation system 400, the inkjet head 500, and the discharge circulation system 600 by the driving force of the second pump P2 of the supply circulation system 400.

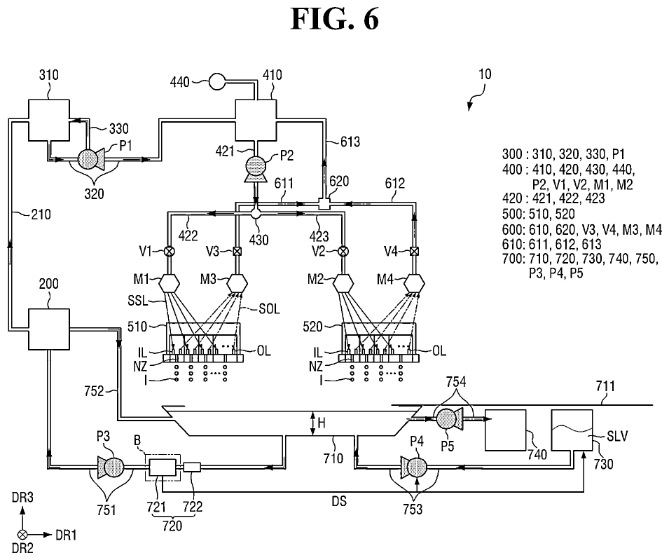

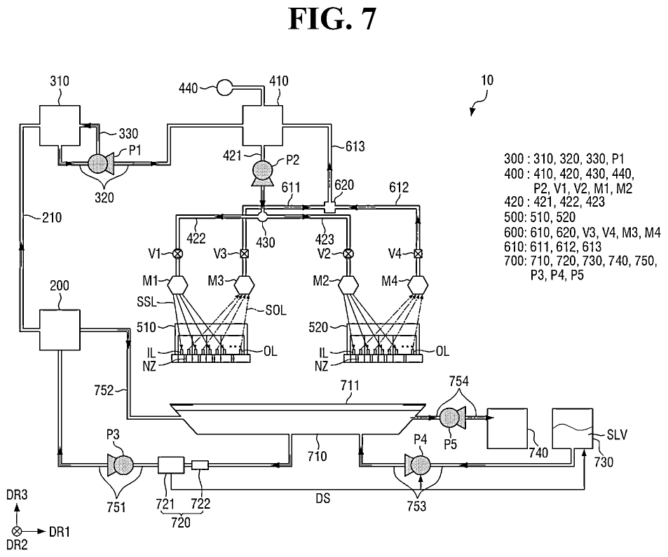

FIG. 6 is a cross-sectional view showing a state in which an inkjet printing device is performing a head care process according to some embodiments. FIG. 7 is a cross-sectional view showing a state in which an inkjet printing device has completed the head care process according to some embodiments.

Referring to FIGS. 6 and 7, the inkjet printing device 10 may perform the head care process. The head care process may refer to a maintenance and repair process that is performed to maintain printing quality by removing deposits or bubbles formed at the inkjet head 500 and preventing or reducing drying of the ink I. The head care process may include a purge process and a spitting process.

The purge process may be a process of continuously discharging the ink I to the outside through the nozzle NZ by forcibly pushing the ink I into the inkjet head 500, for the purpose of maintaining the printing quality and checking the head at the time of replenishing the ink I or in the middle of the printing process.

The spitting process may be a process of periodically ejecting the ink I to the outside of the nozzle NZ to prevent or reduce drying of the ink I in the nozzle NZ when the printing process is idle. According to some embodiments, the inkjet printing device 10 may eject approximately 1 to 10,000 drops of the ink I to the outside at intervals of approximately 1 to 600 seconds during the spitting process.

The inkjet printing device 10 according to some embodiments may reuse, in the printing process, the ink I consumed in the head care process such as the purge process and the spitting process.

According to some embodiments, the inkjet printing device 10 may further include a storage circulation system 700. The storage circulation system 700 may be a circulation system for reusing, in the printing process, the ink I consumed in the head care process such as the purge process and the spitting process. The storage circulation system 700 may include a purge bath 710, a concentration measuring device 720, a solvent supply device 730, a removal tank 740, a storage channel 750, a third pump P3, and a fourth pump P4, and a fifth pump P5.

The purge bath 710 may be a container for collecting the ink I ejected by the head care process. The purge bath 710 may be located under the inkjet head 500 during the head care process. According to some embodiments, the purge bath 710 may have a shape whose width becomes narrower toward the lower portion. For example, the purge bath 710 may have an inverted trapezoidal shape. However, embodiments according to the present disclosure are not limited thereto, and the shape of the purge bath 710 may be variously changed.

According to some embodiments, the inner wall of the purge bath 710 may be subjected to superhydrophobic coating. For example, the inner wall of the purge bath 710 may include a superhydrophobic coating film. Accordingly, it is possible to prevent or reduce instances of the ink I remaining on the inner wall of the purge bath 710 without circulating in the storage circulation system 700. Further, it may be possible to prevent or reduce instances of deposits being formed on the inner wall of the purge bath 710 due to drying of the ink I.

In some embodiments, a level H of the ink I in the purge bath 710 may be maintained at a constant level. For example, when the level H of the ink I in the purge bath 710 is out of a certain level, the third pump P3 may operate to adjust the level of the purge bath 710. Accordingly, the distance between the surface of the ink I in the purge bath 710 and the inkjet head 500 may be maintained at a constant level. When the ink I ejected from the inkjet head 500 falls on the surface of the ink I in the purge bath 710, the scattering thereof to the outside may be prevented or reduced.

In some embodiments, the purge bath 710 may include a door 711. The door 711 may control opening and closing of the purge bath 710. For example, the door 711 may be opened when the head care process is in progress as shown in FIG. 6, and the door 711 may be closed when the head care process is idle as shown in FIG. 7. According to some embodiments, the door 711 may include a separate door driver capable of providing a driving force to the door 711.

The concentration measuring device 720 may include a densitometer 721 and a filter 722.

The densitometer 721 may be located between the purge bath 710 and the ink supply device 200. For example, the densitometer 721 may be located in a first storage channel 751 that connects the purge bath 710 and the ink supply device 200.

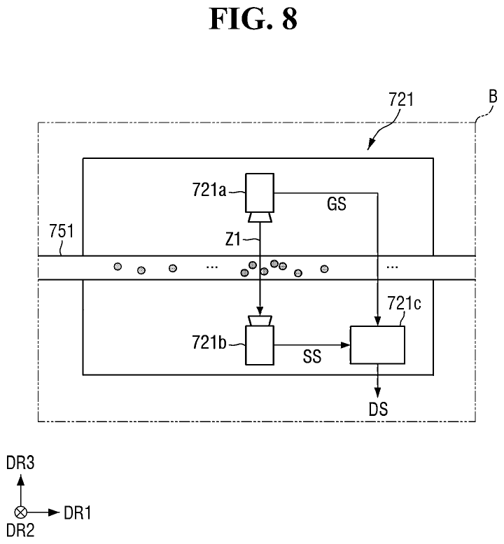

The densitometer 721 may measure the concentration of the ink I moving from the purge bath 710 to the ink supply device 200. The inkjet printing device 10 according to some embodiments includes the densitometer 721, so that the concentration of the ink I may be maintained at a constant level. Accordingly, the reliability of the quality of the ink I may be improved. The specific structure of the densitometer 721 will be described later with reference to FIGS. 8 to 10.

The filter 722 may remove foreign substances contained in the ink I moving from the purge bath 710 to the ink supply device 200. For example, if the door 711 of the purge bath 710 is open during the head care process, external contaminants such as dust or other foreign substances may permeate into the purge bath 710. The filter 722 may prevent or reduce instances of contaminants such foreign substances moving to the ink supply device 200.

The filter 722 may be located between the densitometer 721 and the purge bath 710. Because the filter 722 removes foreign substances contained in the ink I flowing into the densitometer 721, it may be possible to prevent or reduce the concentration of the ink I from being incorrectly measured due to the foreign substances contained in the ink I.

The solvent supply device 730 may control the concentration of the ink I in the purge bath 710. For example, the solvent supply device 730 may supply a solvent SLV to the purge bath 710. The solvent SLV may refer to a liquid component for dissolving a solute contained in the ink I that is an example of the solution. As described above, the solvent SLV may include different materials depending on the configuration of the display device DD (see FIG. 1) to be printed.

Due to the characteristics of the printing process, the solvent SLV may have high volatility. Accordingly, when the ink I remains or circulates in the inkjet printing device 10 for a certain period of time or longer, the solvent SLV component of the ink I may volatilize and the concentration of the ink I may increase. The inkjet printing device 10 according to some embodiments includes the solvent supply device 730 for supplying the solvent SLV to the purge bath 710, so that the concentration of the ink I may be maintained at a constant level.

The removal tank 740 may be a container for temporarily storing or discharging the ink I that is contaminated and cannot be reused. The removal tank 740 may prevent or reduce instances of or the amount of the ink I that is contaminated and cannot be reused flowing into the ink supply device 200 through the first storage channel 751.

The inkjet printing device 10 according to some embodiments includes the separate removal tank 740, so that the ink I that is contaminated and cannot be reused is prevented or reduce from flowing into the ink supply device 200, the buffer circulation system 300, the supply circulation system 400, the inkjet head 500, and the discharge circulation system 600, thereby preventing or reducing the contamination thereof.

The storage channel 750 may include one or more storage channels 751, 752, 753, and 754. For example, the storage channel 750 may include the first storage channel 751, a second storage channel 752, a third storage channel 753, and a fourth storage channel 754.

The first storage channel 751 may connect the purge bath 710 and the ink supply device 200. At least some of the ink I in the purge bath 710 may move to the ink supply device 200 through the first storage channel 751. At least some of the ink I that has moved from the purge bath 710 to the ink supply device 200 may return to the buffer circulation system 300 and the supply circulation system 400 to be reused in the printing process. Accordingly, the ink I consumed in the head care process may be reused in the printing process.

The second storage channel 752 may connect the ink supply device 200 and the purge bath 710. At least some of the ink I of the ink supply device 200 may return to the purge bath 710 through the second storage channel 752. In the inkjet printing device 10 according to some embodiments, a circulation system circulating the ink supply device 200 and the purge bath 710 may be formed by the first storage channel 751 and the second storage channel 752. Accordingly, even if the solvent supply device 730 for adjusting the concentration by injecting the solvent is connected to the purge bath 710, the constant concentration of the ink I may be maintained even in the supply device 200 due to one circulation system in which the ink supply device 200 and the purge bath 710 are connected to each other. Further, the flow amount between the ink supply device 200 and the purge bath 710 is maintained, so that precipitation of the ink I in the ink supply device 200 and the purge bath 710 may be prevented or reduced.

The third storage channel 753 may connect the solvent supply device 730 and the purge bath 710. At least some of the solvent SLV of the solvent supply device 730 may move to the purge bath 710 through the third storage channel 753. Accordingly, the concentration of the ink I in the purge bath 710 and the ink supply device 200 may be maintained at a constant level.

The fourth storage channel 754 may connect the purge bath 710 and the removal tank 740. At least some of the ink I in the purge bath 710, for example, the ink I that is contaminated and cannot be reused, may move to the removal tank 740 through the fourth storage channel 754. The inkjet printing device 10 according to some embodiments includes the separate fourth storage channel 754 that is not connected to the ink supply device 200, so that the ink I that is contaminated and cannot be reused is prevented or reduced from flowing into the ink supply device 200, the buffer circulation system 300, the supply circulation system 400, the inkjet head 500, and the discharge circulation system 600, thereby preventing or reducing the contamination thereof.

The third pump P3 may provide a driving force so that the ink I collected in the purge bath 710 may move to the ink supply device 200 through the first storage channel 751. For example, the third pump P3 may be a fluid pump that transmits a power to a fluid such as the ink I.

The fourth pump P4 may provide a driving force so that the solvent SLV of the solvent supply device 730 may move to the purge bath 710 through the third storage channel 753. For example, the fourth pump P4 may be a fluid pump that transmits a power to a fluid such as the solvent SLV.

The fifth pump P5 may provide a driving force so that the ink I in the purge bath 710, which is contaminated and cannot be reused, may move to the removal tank 740 through the fourth storage channel 754. For example, the fifth pump P5 may be a fluid pump that transmits a power to a fluid such as the ink I.

In some embodiments, the third pump P3 and/or the solvent supply device 730 may receive a driving signal DS from the densitometer 721. The third pump P3 and/or the solvent supply device 730 may supply a required amount of the solvent SLV to the purge bath 710 based on the driving signal DS. In the inkjet printing device 10 according to some embodiments, the third pump P3 and/or the solvent supply device 730 may automatically supply the solvent SLV to the purge bath 710 by the driving signal DS provided from the densitometer 721. Accordingly, the process efficiency may be improved, and the reliability of the quality of the ink I may be improved.

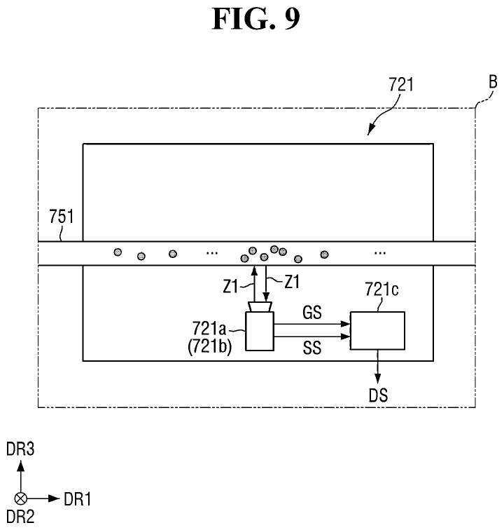

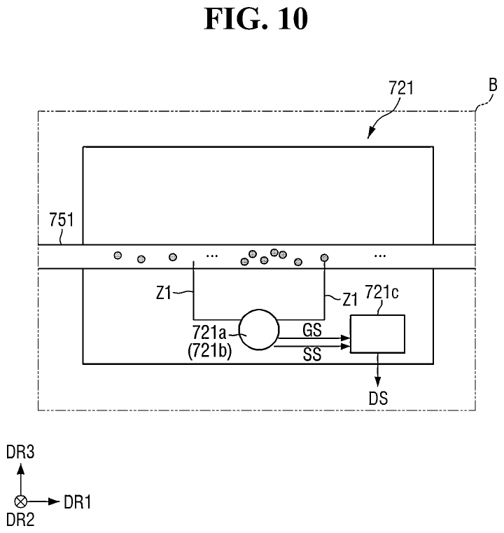

FIG. 8 is an enlarged view of area B of FIG. 6. FIG. 9 is a schematic block diagram showing a densitometer according to some embodiments. FIG. 10 is a schematic block diagram showing a densitometer according to some embodiments.

Referring to FIGS. 8 to 10 in addition to FIG. 6, in some embodiments, the densitometer 721 may include a measurement source generator 721a, a measurement source detector 721b, and a controller 721c.

The measurement source generator 721a may generate a measurement source Z1. The measurement source Z1 generated from the measurement source generator 721a may be detected by the measurement source detector 721b after it interacts with the ink I in the first storage channel 751. The measurement source generator 721a may provide a generation signal GS including information on the generated measurement source Z1 to the controller 721c.

The measurement source detector 721b may detect the measurement source Z1 that has interacted with the ink I in the first storage channel 751. The measurement source detector 721b may provide a sensing signal SS including information on the detected measurement source Z1 to the controller 721c.

The controller 721c may measure the concentration of the ink I by comparing the information on the measurement source Z1 included in the generation signal GS with the information on the measurement source Z1 included in the sensing signal SS. When the measured concentration of the ink I is different from a reference value, the controller 721c may provide the driving signal DS to the third pump P3 and/or the solvent supply device 730.

The third pump P3 that has received the driving signal DS may provide a driving force so that the solvent SLV of the solvent supply device 730 may move to the purge bath 710. The solvent supply device 730 that has received the solvent driving signal DS may supply the solvent SLV to the purge bath 710.

According to some embodiments, the densitometer 721 may include an optical densitometer. For example, when the densitometer 721 includes the optical densitometer, the measurement source generator 721a and the measurement source detector 721b may be located on opposite sides with the first storage channel 751 interposed therebetween, as shown in FIG. 8. The measurement source generator 721a may irradiate light as the measurement source Z1 toward the measurement source detector 721b. As the light as the measurement source Z1 passes through the ink I, the intrinsic energy such as luminance or the like may decrease depending on the concentration of the ink I. The measurement source detector 721b may measure the intrinsic energy of the light that has passed through the ink I. The controller 721c may measure the concentration of the ink I by comparing the intrinsic energy value of the light originally generated by the measurement source generator 721a with the intrinsic energy value of the light detected by the measurement source detector 721b.

According to some embodiments, the densitometer 721 may include a sound wave type densitometer. For example, when the densitometer 721 includes the sound wave type densitometer, the measurement source generator 721a and the measurement source detector 721b may be integrated as shown in FIG. 9. However, embodiments according to the present disclosure are not limited thereto, and the measurement source generator 721a and the measurement source detector 721b may be configured separately, but may be located on the same side with respect to the first storage channel 751. The measurement source generator 721a may emit a sound wave as the measurement source Z1 toward the ink I in the first storage channel 751. As the sound wave as the measurement source Z1 is reflected by the ink I, the intrinsic energy such as an amplitude or the like may decrease depending on the concentration of the ink I. The measurement source detector 721b may measure the intrinsic energy of the sound wave reflected by the ink I. The controller 721c may measure the concentration of the ink I by comparing the intrinsic energy value of the sound wave originally generated by the measurement source generator 721a with the intrinsic energy value of the sound wave detected by the measurement source detector 721b.

According to some embodiments, the densitometer 721 may include an electronic densitometer. For example, when the densitometer 721 includes the electronic densitometer, the measurement source generator 721a and the measurement source detector 721b may be integrated as shown in FIG. 10. The measurement source generator 721a may apply a voltage to the ink I in the first storage channel 751 so that a current as the measurement source Z1 may flow. The magnitude of a resistance or the intensity of a current as the measurement source Z1 may be different depending on the concentration of the ink I. The measurement source detector 721b may measure the magnitude of the resistance or the intensity of the current flowing through the ink I. The controller 721c may measure the concentration of the ink I by comparing the voltage generated by the measurement source generator 721a with the magnitude of the resistance or the intensity of the current detected by the measurement source detector 721b.

The inkjet printing device 10 according to some embodiments includes the densitometer 721, so that the concentration of the ink I may be maintained at a constant level. Accordingly, the reliability of the quality of the ink I may be improved. Further, the third pump P3 and/or the solvent supply device 730 may automatically supply the solvent SLV to the purge bath 710 in response to the driving signal DS provided from the densitometer 721. Accordingly, the process efficiency may be improved.

Hereinafter, aspects of inkjet printing device according to some embodiments will be described in more detail. In the following embodiments, description of the same components as those of the above-described embodiments, which are denoted by like reference numerals, may be omitted or simplified, and differences will be mainly described.

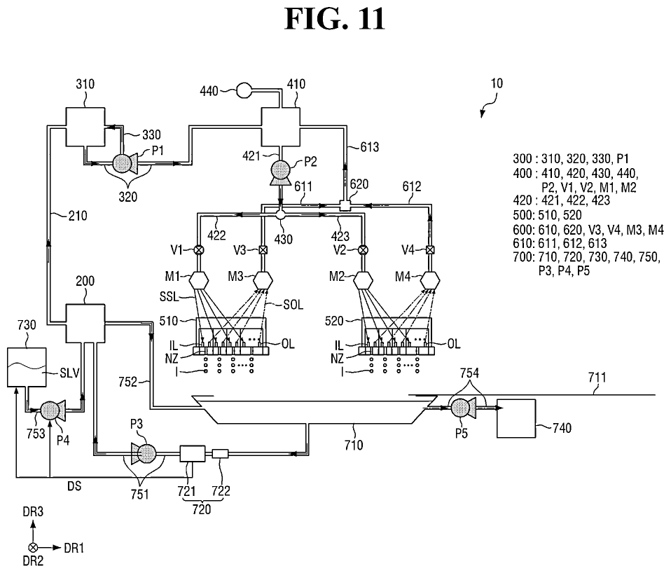

FIG. 11 is a cross-sectional view of an inkjet printing device according to some embodiments.

Referring to FIG. 11, the inkjet printing device 10 according to some embodiments is different from the inkjet printing device 10 according to some embodiments as described with reference to FIG. 6 or the like in that the solvent supply device 730 is connected to the ink supply device 200.

More specifically, the solvent supply device 730 may adjust the concentration of the ink I in the ink supply device 200. For example, the solvent supply device 730 may supply the solvent SLV to the ink supply device 200. The inkjet printing device 10 according to some embodiments includes the solvent supply device 730 for supplying the solvent SLV to the ink supply device 200, so that the concentration of the ink I may be maintained at a constant level.

The second storage channel 752 may connect the ink supply device 200 and the purge bath 710. At least some of the ink I of the ink supply device 200 may return to the purge bath 710 through the second storage channel 752. In the inkjet printing device 10 according to some embodiments, the circulation system circulating the ink supply device 200 and the purge bath 710 may be formed by the first storage channel 751 and the second storage channel 752. Accordingly, even if the solvent supply device 730 for adjusting the concentration by injecting the solvent is connected to the ink supply device 200, the constant concentration of the ink I may be maintained even in the purge bath 710 due to one circulation system in which the ink supply device 200 and the purge bath 710 are connected to each other. Further, the flow amount between the ink supply device 200 and the purge bath 710 is maintained at a constant level, so that precipitation of the ink I in the ink supply device 200 and the purge bath 710 may be prevented or reduced.

The third storage channel 753 may connect the solvent supply device 730 and the ink supply device 200. At least some of the solvent SLV of the solvent supply device 730 may move to the ink supply device 200 through the third storage channel 753. Accordingly, the concentration of the ink I in the purge bath 710 and the ink supply device 200 may be maintained at a constant level.

The fourth pump P4 may provide a driving force so that the solvent SLV of the solvent supply device 730 may move to the ink supply device 200 through the third storage channel 753.

In some embodiments, the third pump P3 and/or the solvent supply device 730 may receive the driving signal DS from the densitometer 721. The third pump P3 and/or the solvent supply device 730 may supply a required amount of the solvent SLV to the ink supply device 200 based on the driving signal DS. In the inkjet printing device 10 according to some embodiments, the third pump P3 and/or the solvent supply device 730 may automatically supply the solvent SLV to the ink supply device 200 by the driving signal DS provided from the densitometer 721. Accordingly, the process efficiency may be improved.

Although it is illustrated that the solvent supply device 730 is connected to the purge bath 710 in the inkjet printing device 10 according to some embodiments as described with reference to FIG. 6, and the solvent supply device 730 is connected to the ink supply device 200 in the inkjet printing device 10 according to some embodiments, embodiments according to the present disclosure are not limited thereto. For example, the solvent supply device 730 may be connected to both the purge bath 710 and the ink supply device 200. For another example, the solvent supply device 730 may be connected to at least one of the first storage channel 751 or the second storage channel 752.

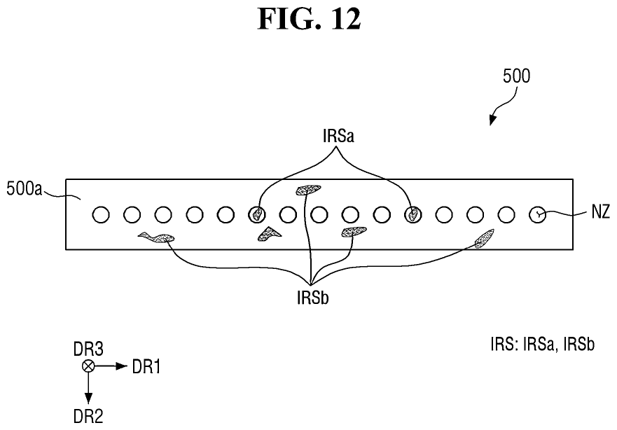

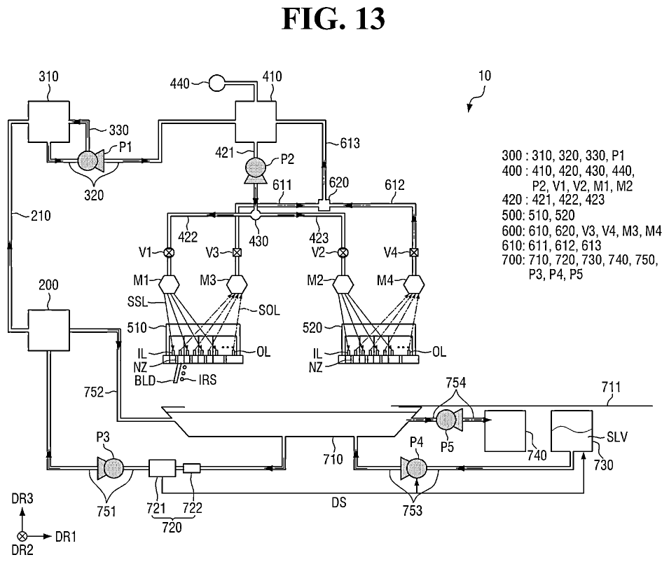

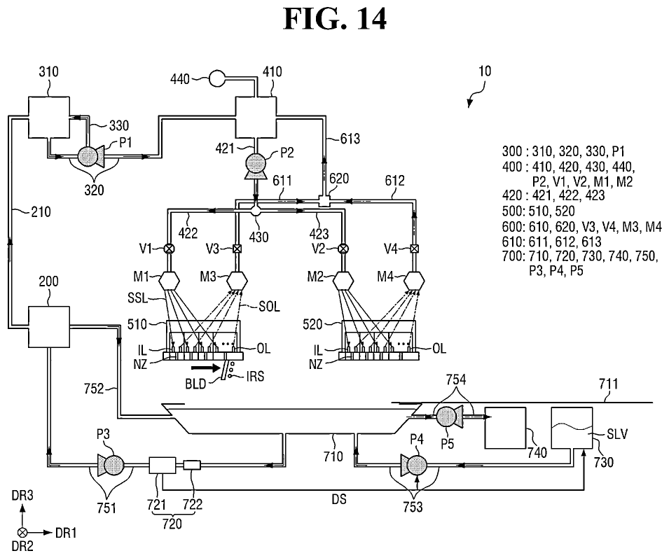

FIG. 12 is a bottom view showing an inkjet head of an inkjet printing device according to some embodiments. FIGS. 13 and 14 are cross-sectional views of an inkjet printing device according to some embodiments.

Referring to FIGS. 12 to 14, the inkjet printing device 10 according to the present embodiments are different from the inkjet printing device 10 according to some embodiments as described with reference to FIG. 6 or the like in that it may be used in a blade wiping process as the head care process.

More specifically, as shown in FIG. 12, the inkjet head 500 may include a plurality of nozzles NZ spaced apart from each other in the first direction DR1 or the second direction DR2. Although it is illustrated in the drawing that the plurality of nozzles NZ are arranged in one row while being spaced apart from each other in the first direction DR1, embodiments according to the present disclosure are not limited thereto. For example, the plurality of nozzles NZ may include a plurality of rows spaced apart from each other in the second direction DR2, and several tens to several thousands of nozzles NZ may be arranged in each row in the first direction DR1. The number and arrangement of the plurality of nozzles NZ are not limited to those shown in the drawing.

After the printing process, or after the head care process such as the purge process and the spitting process, a residual ink IRS may remain on a bottom surface 500a of the inkjet head 500. For example, the residual ink IRS may include a first residual ink IRSa remaining in the nozzle NZ, and a second residual ink IRSb remaining on the bottom surface 500a of the inkjet head 500. When they remain for a long period of time, the first residual ink IRSa may mainly cause clogging of the nozzle NZ, and the second residual ink IRSb may mainly cause contamination of the inkjet head 500.

Due to the head care process such as the purge process and the spitting process, it is possible to remove the first residual ink IRSa remaining in the nozzle NZ, or prevent or reduce instances of the first residual ink IRSa being formed in advance. However, the second residual ink IRSb remaining on the bottom surface 500a of the inkjet head 500 may not be easily removed even by the purge process and the spitting process.

Accordingly, the blade wiping process may also be performed as the head care process of the inkjet printing device 10. As shown in FIGS. 13 and 14, the blade wiping process refers to a process of wiping the bottom surface 500a of the inkjet head 500 using a blade BLD to push and remove the residual ink IRS.

The inkjet printing device 10 according to some embodiments may reuse the residual ink IRS removed in the blade wiping process by the storage circulation system 700. For example, the residual ink IRS removed from the bottom surface 500a of the inkjet head 500 using the blade BLD may be collected into the purge bath 710. The residual ink IRS collected in the purge bath 710 may be reused in the printing process by the storage circulation system 700, as in the inkjet printing device 10 according to some embodiments as described above with reference to FIG. 6 or the like.

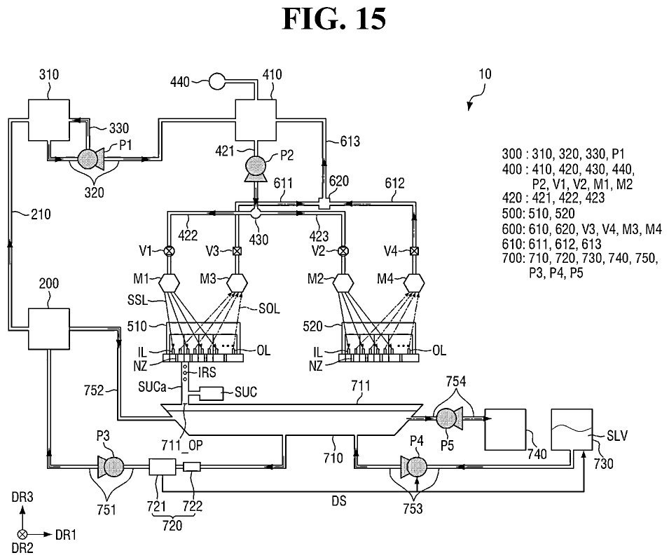

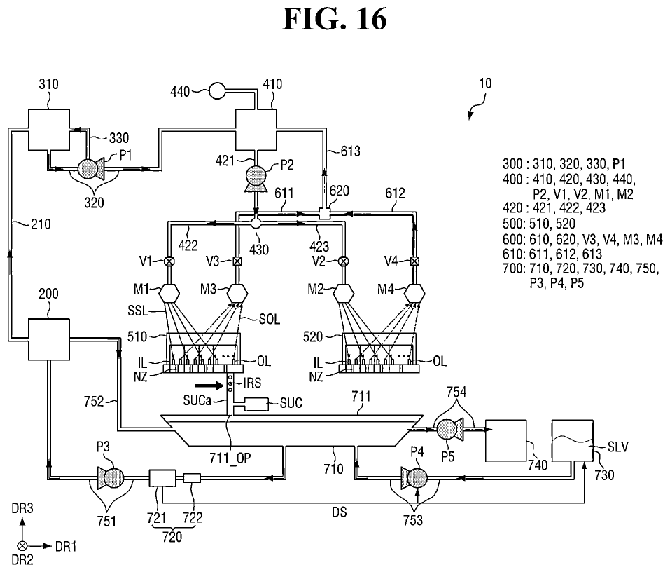

FIGS. 15 and 16 are cross-sectional views of an inkjet printing device according to some embodiments.

Referring to FIGS. 15 and 16 in addition to FIG. 12, the inkjet printing device 10 according to the present embodiments are different from the inkjet printing device 10 according to embodiments described with reference to FIG. 6 or the like in that it may be used in a suction process as the head care process.

More specifically, as described above with reference to FIG. 12, after the printing process, or after the head care process such as the purge process and the spitting process, the residual ink IRS may remain on the bottom surface 500a of the inkjet head 500. For example, the residual ink IRS may include the first residual ink IRSa remaining in the nozzle NZ, and the second residual ink IRSb remaining on the bottom surface 500a of the inkjet head 500. When they remain for a long period of time, the first residual ink IRSa may mainly cause clogging of the nozzle NZ, and the second residual ink IRSb may mainly cause contamination of the inkjet head 500.

Due to the head care process such as the purge process and the spitting process, it is possible to remove the first residual ink IRSa remaining in the nozzle NZ, or prevent or reduce instances of the first residual ink IRSa being formed in advance. However, some of the first residual ink IRSa may remain in the nozzle NZ, and the second residual ink IRSb remaining on the bottom surface 500a of the inkjet head 500 may not be easily removed even by the purge process and the spitting process.

Accordingly, the suction process may also be performed as the head care process of the inkjet printing device 10. As shown in FIGS. 15 and 16, the suction process may be a process of sucking and removing the residual ink IRS using a suction device SUC connected to a suction channel SUCa. For example, the suction device SUC may suck and remove the first residual ink IRSa in the nozzle NZ and the second residual ink IRSb on the bottom surface 500a of the inkjet head 500 through the suction channel SUCa.

The inkjet printing device 10 according to some embodiments may reuse the residual ink IRS removed in the suction process by the storage circulation system 700. For example, the residual ink IRS removed using the suction device SUC connected to the suction channel SUCa may be collected into the purge bath 710. The residual ink IRS collected in the purge bath 710 may be reused in the printing process through the storage circulation system 700, as in the inkjet printing device 10 according to some embodiments described above with reference to FIG. 6 or the like.

In some embodiments, the door 711 of the purge bath 710 may be closed even during the suction process. For example, the door 711 of the purge bath 710 may include a suction opening 711_OP communicating with the suction channel SUCa. The suction opening 711_OP of the door 711 may move along the suction channel SUCa. The other portion of the door 711 except the suction opening 711_OP may seal the purge bath 710. Accordingly, foreign substances permeating into the purge bath 710 may be prevented or reduced. Further, the drying speed of the ink I may be minimized.

In concluding the detailed description, those skilled in the art will appreciate that many variations and modifications can be made to the disclosed embodiments without substantially departing from the spirit and scope of embodiments according to the present disclosure. Therefore, the disclosed embodiments according to the present disclosure are used in a generic and descriptive sense only and not for purposes of limitation.

What is claimed is:

1. An inkjet printing device comprising:
an inkjet head;
an ink supply device connected to the inkjet head;
a purge bath below the inkjet head, and connected to the ink supply device;
a first channel connecting the purge bath and the ink supply device; and
a densitometer in the first channel.

2. The inkjet printing device of claim 1, wherein the densitometer comprises:
a measurement source generator;
a measurement source detector configured to detect a measurement source generated from the measurement source generator; and
a controller configured to receive information on the measurement source from the measurement source detector and the measurement source generator, respectively.

3. The inkjet printing device of claim 2, wherein the measurement source generator and the measurement source detector are located on opposite sides with the first channel interposed therebetween.

4. The inkjet printing device of claim 2, wherein the measurement source generator and the measurement source detector are located on the same side with respect to the first channel.

5. The inkjet printing device of claim 2, wherein the measurement source generated from the measurement source generator is configured to interact with ink located in the first channel.

6. The inkjet printing device of claim 5, wherein
the measurement source generator is configured to provide, to the controller, a first signal containing information on the measurement source generated from the measurement source generator,
the measurement source detector is configured to provide, to the controller, a second signal containing information on the measurement source that has interacted with the ink, and
the controller is configured to generate a third signal based on the first signal and the second signal.

7. The inkjet printing device of claim 6, further comprising a solvent supply device connected to at least one of the purge bath, the first channel, or the ink supply device,
wherein the controller is configured to provide the third signal to the solvent supply device.

8. The inkjet printing device of claim 7, wherein the solvent supply device that has received the third signal is configured to supply a solvent of the ink to at least one of the purge bath, the first channel, or the ink supply device.

9. The inkjet printing device of claim 1, further comprising a filter between the densitometer and the purge bath.

10. The inkjet printing device of claim 1, wherein the purge bath comprises a door configured to control opening and closing of the purge bath.

11. The inkjet printing device of claim 10, wherein the door comprises a door driver configured to provide a driving force to the door.

12. The inkjet printing device of claim 10, further comprising:
a suction channel connecting the inkjet head and the door of the purge bath; and
a suction device connected to the suction channel.

13. The inkjet printing device of claim 12, wherein the door comprises a suction opening communicating with the suction channel, and
the suction opening is configured to move along the suction channel.

14. The inkjet printing device of claim 1, wherein an inner wall of the purge bath comprises a superhydrophobic coating film.

15. The inkjet printing device of claim 1, wherein a level of the ink in the purge bath is maintained at a constant level.

16. The inkjet printing device of claim 1, further comprising a removal tank connected to the purge bath,
wherein the removal tank is not connected to the ink supply device.

17. The inkjet printing device of claim 1, further comprising a second channel connecting the purge bath and the ink supply device, and different from the first channel,
wherein ink flow directions of the first channel and the second channel are different.

18. The inkjet printing device of claim 1, further comprising a blade located between the inkjet head and the purge bath,
wherein the blade is configured to wipe a bottom surface of the inkjet head.

19. An inkjet printing device comprising:
an ink supply device;
an ink storage device configured to receive ink from the ink supply device;
an inkjet head configured to receive ink from the ink storage device;
a purge bath configured to collect ink ejected from the inkjet head;
a first channel configured to move the ink from the purge bath to the ink supply device;
a densitometer configured to measure a concentration of the ink located in the first channel; and
a solvent supply device configured to supply a solvent of the ink to at least one of the ink supply device, the purge bath, or the first channel.

20. The inkjet printing device of claim 19, further comprising a first pump in the first channel, and configured to provide a driving force from the purge bath toward the ink supply device.

21. The inkjet printing device of claim 20, further comprising a second channel different from the first channel, and configured to move the ink from the ink supply device to the purge bath.

22. The inkjet printing device of claim 21, further comprising a third channel configured to move the solvent of the ink from the solvent supply device to at least one of the ink supply device, the purge bath, or the first channel.

23. The inkjet printing device of claim 22, further comprising a second pump in the third channel, and configured to provide a driving force from the solvent supply device toward at least one of the ink supply device, the purge bath, or the first channel.
